(19) United States
(12) Patent Application Publication
(10) Pub. No.: US 2017/0117027 A1
(43) Pub. Date: Apr. 27, 2017

(54) TOP PINNED SOT-MRAM ARCHITECTURE WITH IN-STACK SELECTOR

(71) Applicant: HGST Netherlands B.V., Amsterdam (NL)

(72) Inventors: Patrick M. BRAGANCA, San Jose, CA (US); Lei WAN, San Jose, CA (US)

(73) Assignee: HGST NETHERLANDS B.V.

(21) Appl. No.: 14/919,247

(22) Filed: Oct. 21, 2015

(51) Int. Cl. G11C 11/16; H01L 43/02; H01L 43/08; H01L 27/22

(52) U.S. Cl. CPC G11C 11/161; G11C 11/1675; H01L 27/224; H01L 43/02; H01L 43/08

(57) ABSTRACT

Embodiments of the present disclosure generally relate to data storage and computer memory systems, and more particularly, to a SOT-MRAM cell and chip architecture. The SOT-MRAM chip architecture includes a memory cell array having a plurality of first leads, a plurality of second leads, and a plurality of memory cells. Each memory cell of the plurality of memory cells includes a MTJ and a selector element. These SOT-MRAM cells eliminate the need to pass large currents through the barrier layer of the MTJ and the selector element eliminates the large transistors usually required for selecting a single memory cell without disturbing neighboring memory cells.

### BACKGROUND OF THE DISCLOSURE

Field of the Disclosure

Embodiments of the present disclosure generally relate to data storage and computer memory systems, and more particularly, to a spin-orbit torque magnetoresistive random access memory (SOT-MRAM) cell and chip architecture.

Description of the Related Art

The heart of a computer is a magnetic recording device which typically may include a rotating magnetic media or a solid state media device. A number of different memory technologies exist today for storing information for use in a computing system. These different memory technologies may, in general, be split into two major categories: volatile memory and non-volatile memory. Volatile memory may generally refer to types of computer memory that require power to retain stored data. Non-volatile memory, on the other hand, may generally refer to types of computer memory that do not require power in order to retain stored data. Examples of volatile memory may include certain types of random access memory (RAM), such as dynamic RAM (DRAM) and static RAM (SRAM). Examples of non-volatile memory may include read-only memory (ROM), magnetoresistive RAM (MRAM), and flash memory, such as NOR and NAND flash, etc.

In recent years there has been a demand for higher density devices, which maintain a relatively low cost per bit, for use in high capacity storage and memory applications. Today the memory technologies that generally dominate the computing industry are DRAM and NAND flash; however these memory technologies may not be able to address the current and future capacity demands of next generation computing systems.

Recently, a number of emerging technologies have drawn increasing attention as potential contenders for next generation memory. One such memory technology is magnetoresistive random access memory (MRAM). MRAM offers fast access time, nearly infinite read/write endurance, radiation hardness, and high storage density. Unlike conventional RAM chip technologies, MRAM data is not stored as an electric charge, but instead stores data bits using the magnetic polarization state of magnetic elements. The elements are formed from two magnetically polarized layers, each of which can maintain a magnetic polarization field, separated by a thin insulating layer, which together form a magnetic tunnel junction (MTJ) structure. MRAM cells including MTJ memory elements can be designed for in-plane or perpendicular magnetization of the MTJ layer structure with respect to the film surface. One of the two layers (referred to as a fixed or reference layer) has its magnetization fixed and set to a particular polarity, for example by coupling the layer to an antiferromagnet; the polarization of the second layer (referred to as a free layer) is free to rotate under the influence of an external writing mechanism such as a strong magnetic field or a spin polarized electric current (which is used in a form of MRAM know as spin-torque transfer or STT-MRAM).

However, the MTJ memory elements in STT-MRAM devices suffer from wear-effects due to driving a sufficient amount of current for switching through the MTJ, including through the barrier layer. Typically, a large amount of current is required for switching the state of the cell. Over time, the barrier layer breaks down due to the large amount of current, rendering the MTJ useless. Additionally, in STT-MRAM devices, it can be difficult to isolate a single MTJ element without disturbing neighboring MTJ elements, and a large transistor, such as a complementary metal oxide semiconductor (CMOS) transistor, may be necessary in the device in order to select an individual MTJ element.

Therefore, there is a need in the art for an improved MRAM device.

### SUMMARY

Embodiments of the present disclosure generally relate to data storage and computer memory systems, and more particularly, to a SOT-MRAM cell and chip architecture. The SOT-MRAM chip architecture includes a memory cell array having a plurality of first leads, a plurality of second leads, and a plurality of memory cells. Each memory cell of the plurality of memory cells includes both a MTJ and a selector element. These SOT-MRAM cells eliminate the need to pass large currents through the barrier layer of the MTJ and the selector element eliminates the large transistors usually required for selecting a single memory cell without disturbing neighboring memory cells.

In one embodiment, a memory cell includes a MTJ and a selector element disposed on the MTJ.

In another embodiment, a memory cell array includes a plurality of first leads, a plurality of second leads, and a plurality of memory cells disposed between the plurality of first leads and the plurality of second leads. Each memory cell of the plurality of memory cells includes a MTJ and a selector element disposed on the MTJ.

In another embodiment, a SOT-MRAM includes a memory cell array having a plurality of first leads, a plurality of second leads, and a plurality of memory cells disposed between the plurality of first leads and the plurality of second leads. Each memory cell of the plurality of memory cells includes a MTJ and a selector element disposed on the MTJ.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a memory cell array according to one embodiment described herein.

FIG. 2 is a schematic perspective view of the memory cell array according to one embodiment described herein.

FIG. 3 is a cross sectional side view of a first lead, a second lead, and a memory cell along a line III-III shown in FIG. 2, according to one embodiment described herein.

FIG. 4 is a cross sectional side view of the first lead, the second lead, and the memory cell along the line III-III shown in FIG. 2, according to one embodiment described herein.

FIG. 5 is a cross sectional side view of the first lead, the second lead, and the memory cell along the line III-III shown in FIG. 2, according to one embodiment described herein.

FIG. 6 is a cross sectional side view of a selector element according to one embodiment described herein.

FIG. 7 is a cross sectional side view of a selector element according to another embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

Embodiments of the present disclosure generally relate to data storage and computer memory systems, and more particularly, to a SOT-MRAM cell and chip architecture. The SOT-MRAM chip architecture includes a memory cell array having a plurality of first leads, a plurality of second leads, and a plurality of memory cells. Each memory cell of the plurality of memory cells includes a MTJ and a selector element. These SOT-MRAM cells eliminate the need to pass large currents through the barrier layer of the MTJ and the selector element eliminates the large transistors usually required for selecting a single memory cell without disturbing neighboring memory cells.

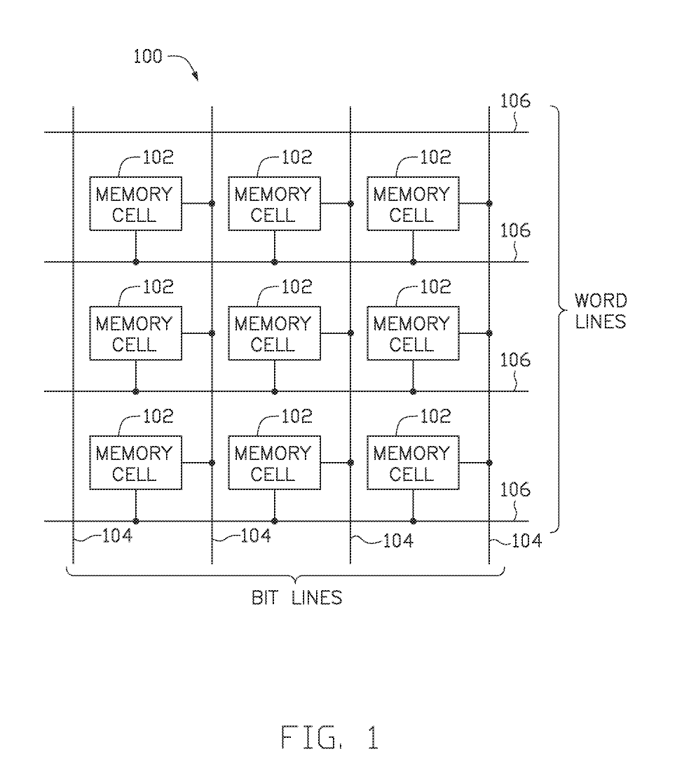

FIG. 1 is a schematic diagram of a memory cell array 100 according to one embodiment described herein. The memory cell array 100 may be a portion of a SOT-MRAM cell and chip architecture. The memory cell array 100 may include a plurality of first leads 104, a plurality of second leads 106, and a plurality of memory cells 102. The plurality of first leads 104 may be substantially parallel among each other, the plurality of second leads 106 may be substantially parallel among each other, and each first lead 104 may be substantially perpendicular to each second lead 106. The plurality of first leads 104 may be disposed over the plurality of second leads 106, and each memory cell 102 may be disposed between a first lead 104 and a second lead 106. The plurality of first leads 104 may be bit lines and the plurality of second leads 106 may be word lines. Four first leads 104 and four second leads 106 are illustrated in FIG. 1, but the memory cell array 100 may include more than four first leads 104 and second leads 106.

FIG. 2 is a schematic perspective view of the memory cell array 100 according to one embodiment described herein. As shown in FIG. 2, the plurality of first leads 104 are disposed over the plurality of second leads 106, and the plurality of first leads 104 are substantially perpendicular to the plurality of second leads 106. Each memory cell 102 of the plurality of memory cells 102 is disposed between a first lead 104 and a second lead 106 at a location that the first lead 104 and the second lead 106 cross over or intersect. Each memory cell 102 may be in contact with a first lead 104 and a second lead 106.

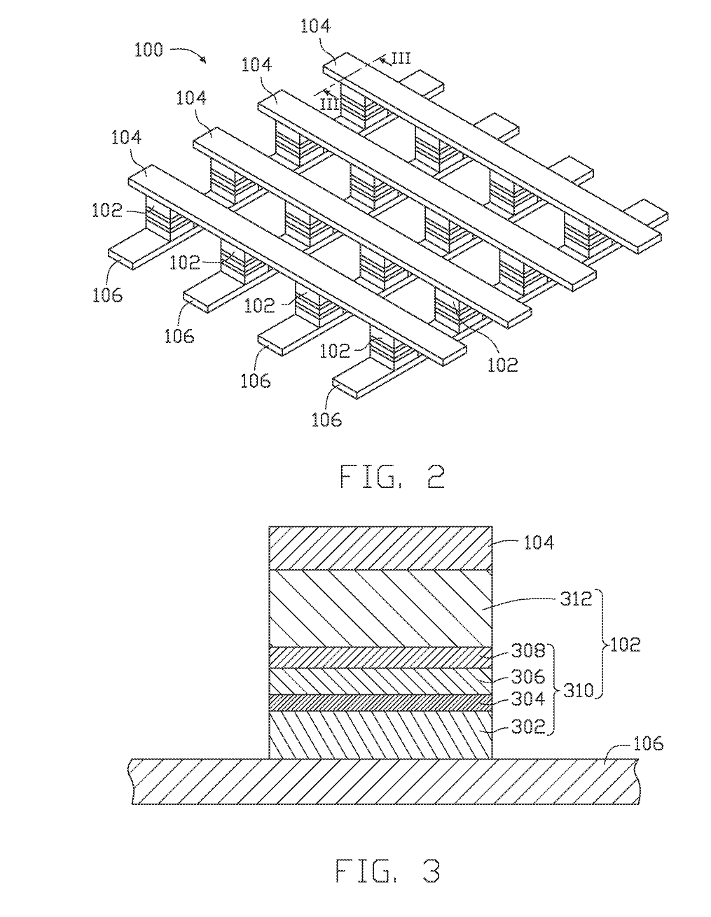

FIG. 3 is a cross sectional side view of a first lead 104 of the plurality of first leads 104, a second lead 106 of the plurality of second leads 106, and a memory cell 102 of the plurality of memory cells 102 along a line III-III shown in FIG. 2, according to one embodiment described herein. As shown in FIG. 3, the memory cell 102 may be disposed on and in contact with the second lead 106, and the first lead 104 may be disposed on and in contact with the memory cell 102. The second lead 106 may be made of a material having large spin-orbit coupling strength, such as Pt, Ta, W, Hf, Ir, CuBi, CuIr, or AuW. Materials having large spin-orbit coupling strength may have high electrical resistivity, such as from about 150 μΩcm to about 250 μΩcm. The electrical resistivity of the material having large spin-orbit coupling strength is typically much greater than the electrical resistivity of conductive metals, such as Cu. The memory cell 102 may include a MTJ 310 having a free layer 302, a barrier layer 304, a reference layer 306, and a capping layer 308. The free layer 302 may be disposed on and in contact with the second lead 106. The free layer 302 may have its magnetic polarization either in the film plane or perpendicular to the film plane and may comprise one of Ni, Fe, Co, B, Ge, Mn, and/or alloys of Ni, Fe, Co, B, Ge, or Mn, and/or combinations and mixtures thereof, such as NiFe, CoFe, or CoFeB. The barrier layer 304 may be made of a nonmagnetic metal such as Cu or Ag, or an insulating material such as alumina, MgO, or HfO. The reference layer 306 may also have its magnetic polarization either in the film plane or perpendicular to the film plane and may comprise one of Ni, Fe, Co, B, Ge, Mn, and/or alloys of Ni, Fe, Co, B, Ge, or Mn, and/or combinations and mixtures thereof, such as NiFe, CoFe, or CoFeB, and/or Co/Pt, Co/Pd, or Co/Ni superlattices. The capping layer 308 may be made of a nonmagnetic metal, such as Cu, Ru, Ta, Au, or Al.

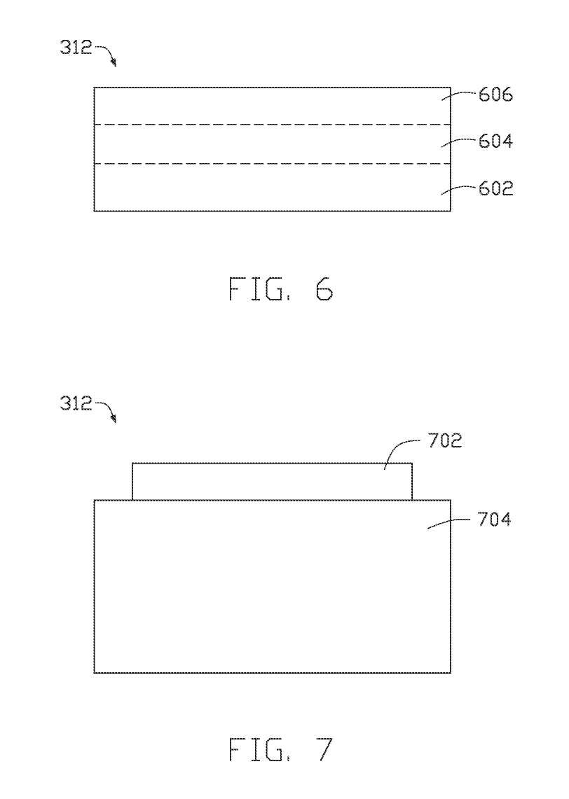

A selector element 312 may be disposed on and in contact with the MTJ 310. The selector element 312 may be a diode or another similar nonlinear device that has asymmetric conductance (i.e., low resistance to current in one direction while high resistance in the other). In one embodiment, the selector 312 is a p-n junction semiconductor diode. As shown in FIG. 6, the selector 312 may be a semiconductor diode having a p-type region 602, an n-type region 606, and a p-n junction 604. The p-type region 602 may be a semiconductor material doped with p-type dopants, such as boron, and the n-type region 606 may be a semiconductor material doped with n-type dopants, such as phosphorus. In another embodiment, the selector 312 may be a metal-semiconductor Schottky diode. As shown in FIG. 7, the selector may be a diode having a metal layer 702 and a semiconductor layer 704. The metal layer 702 may comprise materials such as Au and Al, and the semiconductor layer 704 may be made of an n-type material. The capping layer 308 may also serve as a spacer layer separating the selector 312 from the MTJ element 310. The first lead 104 may be disposed on and in contact with the selector 312. The first lead 104 may be made of a conductive metal, such as Cu or aluminum. The first lead 104 may have a lower electrical resistivity than the second lead 106.

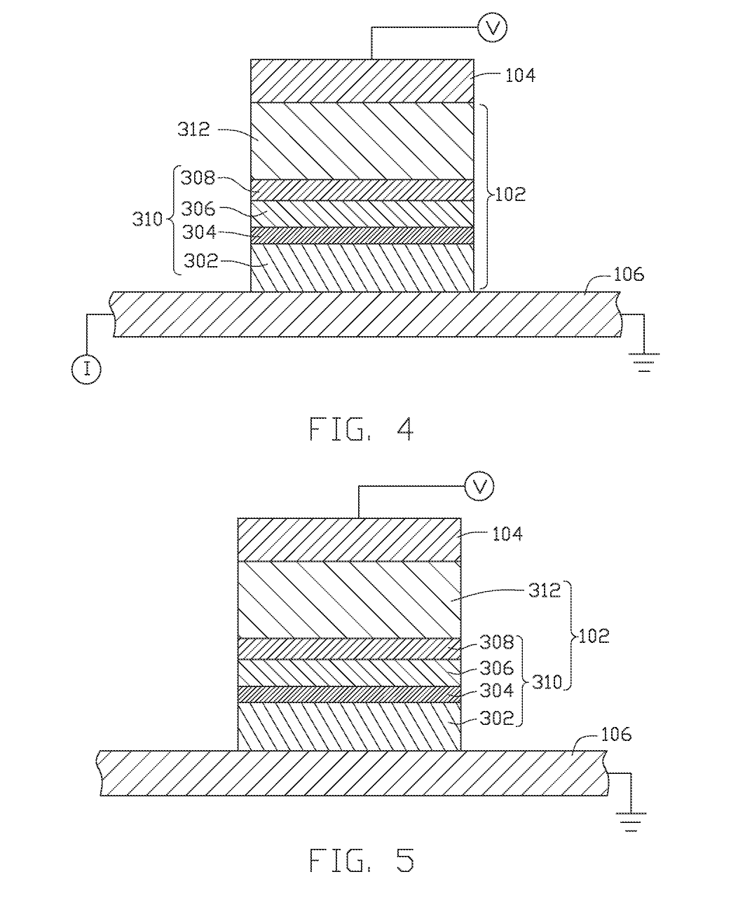

During operation, writing can be done by a half-select mechanism which includes the combination of flowing a current along the second lead 106 and applying a voltage to the first lead 104, as shown in FIG. 4. Spin orbit torques (SOT) can originate from spin hall or Rashba effects which are generated by the current flowing along the second lead 106. Flowing the current along the second lead 106 alone is not enough to switch the state of the memory cell 102. In one embodiment, the current flowing along the second lead 106 is half of a current that would cause the memory cell 102 to switch. In order to select a particular memory cell 102 for writing process, a voltage is applied to the first lead 104 at the particular memory cell 102 to generate a voltage controlled magnetic anisotropy (VCMA) effect. The VCMA effect can be explained in terms of the electric-field-induced change of occupancy of atomic orbitals at the interface in the MTJ of the memory cell 102, which, in conjunction with spin-orbit interaction, results in a change of anisotropy. For example, a decrease in the electron density at the interface increases perpendicular anisotropy. Since this magnetoelectric coupling is not strain-mediated, it is not endurance limited, making it compatible with logic and memory applications. The combination of SOT and VCMA selects the particular memory cell 102 for writing process. Here, the resistance of the barrier layer 304 is tuned to be large enough that the current flowing between the first lead 104 and the second lead 106 through the barrier layer 304 is relatively small, and the free layer 302 is protected from process damage since the free layer 302 is located at the bottom of the stack.

In another embodiment, the barrier layer 304 resistance can be made low enough that the current across the MTJ of a particular memory cell 102 is half the current that would cause the memory cell 102 to switch. Here, a combination of SOT and direct spin torque transfer from the current selects the particular memory cell 102 for writing process.

Conventionally, a plurality of transistors, such as CMOS transistors, are electrically coupled to the second lead in order to select a particular memory cell for reading process. Since a current is flowing along the second lead 106, the transistors may be shorted together, resulting in sneak paths to other memory cells and in degraded performance. In order to reduce or eliminate sneak paths, the CMOS transistors are replaced by the selector element 312 in each memory cell 102. During reading operation, the second lead 106 may be grounded or biased, and a voltage is applied to the first lead 104, as shown in FIG. 5. The polarity of the voltage is chosen so a current can flow in a direction from the second lead 106 to the first lead 104 (i.e., the selector 312 is in high conductivity state). The selector element 312 allows the current to flow through in one direction. Thus, the selector element 312 in neighboring memory cells 102 prevent the current flowing from the first lead 104 to the second lead 106. As a result, sneak paths are reduced or eliminated.

In summary, a SOT-MRAM cell and chip architecture including a memory array is disclosed. The memory array includes a plurality of first leads, a plurality of second leads, and a plurality of memory cells. Each memory cell includes a MTJ and a selector element. The second leads may be made of a material having large spin-orbit coupling strength, which generates SOT when a current is flowing along the second lead. The MTJ may include a free layer disposed on and in contact with the second lead. Since the free layer is disposed at the bottom of the MTJ, the free layer is protected from process damage. The selector element in each memory cell may be utilized in order to eliminate the use of large transistors for selecting memory cells for read process. The selector can also prevent sneak paths which lead to improvements in performance of the SOT-MRAM cell and chip architecture.

While the foregoing is directed to embodiments of the disclosure, other and further embodiments may be devised without departing from the basic scope thereof, and the scope thereof is determined by the claims that follow.

What is claimed is:

1. A memory cell, comprising:
a magnetic tunnel junction; and
a selector element disposed on the magnetic tunnel junction.

2. The memory cell of claim 1, wherein the magnetic tunnel junction comprises:
a ferromagnetic free layer;
a barrier layer disposed on and in contact with the ferromagnetic free layer;
a ferromagnetic reference layer disposed on and in contact with the barrier layer; and
a capping layer disposed on and in contact with the ferromagnetic reference layer, wherein the selector is disposed on and in contact with the capping layer.

3. The memory cell of claim 2, wherein the ferromagnetic free layer has a magnetic polarization in a film plane or perpendicular to the film plane.

4. The memory cell of claim 2, wherein the ferromagnetic reference layer has a magnetic polarization in a film plane or perpendicular to the film plane.

5. The memory cell of claim 1, wherein the selector element is a Schottky diode having a metal layer and a semiconductor layer.

6. The memory cell of claim 1, wherein the selector element is a semiconductor diode having a p-n junction.

7. A memory cell array, comprising:
a plurality of first leads;
a plurality of second leads; and
a plurality of memory cells disposed between the plurality of first leads and the plurality of second leads, wherein each memory cell of the plurality of memory cells comprises:
a magnetic tunnel junction; and
a selector element disposed on the magnetic tunnel junction.

8. The memory cell array of claim 7, wherein each memory cell of the plurality of memory cells is disposed at a location that a first lead of the plurality of first leads and a second lead of the plurality of second leads cross over.

9. The memory cell array of claim 7, wherein the magnetic tunnel junction of each memory cell of the plurality of memory cells comprises:
a ferromagnetic free layer;
a barrier layer disposed on and in contact with the ferromagnetic free layer;
a ferromagnetic reference layer disposed on and in contact with the barrier layer; and
a capping layer disposed on and in contact with the ferromagnetic reference layer, wherein the selector is disposed on and in contact with the capping layer.

10. The memory cell array of claim 9, wherein the ferromagnetic free layer is disposed on and in contact with a second lead of the plurality of second leads, and a first lead of the plurality of first leads is disposed on and in contact with the selector.

11. The memory cell array of claim 7, wherein each first lead of the plurality of first leads has a lower electrical resistivity than each second lead of the plurality of second leads.

12. The memory cell array of claim 11, wherein each first lead of the plurality of first leads comprises copper or aluminum and each second lead of the plurality of second leads comprises a material selected from the group consisting of Pt, Ta, W, Hf, Ir, CuBi, CuIr, and AuW, and wherein a writing process is performed by a half-select mechanism that includes a combination of flowing a current along a second lead of the plurality of second leads and applying a voltage to a first lead of the plurality of first leads.

13. The memory cell array of claim 7, wherein the selector element comprises a diode.

14. The memory cell array of claim 13, wherein the diode is a semiconductor diode having a p-n junction.

15. The memory cell array of claim 7, wherein the selector element is a Schottky diode having a metal layer and a semiconductor layer.

16. A spin-orbit torque magnetoresistive random access memory, comprising:
a memory cell array, comprising:
a plurality of first leads;
a plurality of second leads; and
a plurality of memory cells disposed between the plurality of first leads and the plurality of second leads, wherein each memory cell of the plurality of cells comprises:
a magnetic tunnel junction; and
a selector element disposed on the magnetic tunnel junction.

17. The spin-orbit torque magnetoresistive random access memory of claim 16, wherein the magnetic tunnel junction of each memory cell of the plurality of memory cells comprises:
a ferromagnetic free layer;
a barrier layer disposed on and in contact with the ferromagnetic free layer;
a ferromagnetic reference layer disposed on and in contact with the barrier layer; and
a capping layer disposed on and in contact with the ferromagnetic reference layer, wherein the selector is disposed on and in contact with the capping layer.

18. The spin-orbit torque magnetoresistive random access memory of claim 17, wherein the ferromagnetic free layer is disposed on and in contact with a second lead of the plurality of second leads, and a first lead of the plurality of first leads is disposed on and in contact with the selector.

19. The spin-orbit torque magnetoresistive random access memory of claim 16, wherein each first lead of the plurality of first leads has a lower electrical resistivity than each second lead of the plurality of second leads.

20. The spin-orbit torque magnetoresistive random access memory of claim 19, wherein each first lead of the plurality of first leads comprises copper or aluminum and each second lead of the plurality of second leads comprises a material selected from the group consisting of Pt, Ta, W, Hf, Ir, CuBi, CuIr, and AuW, and wherein a writing process is performed by a half-select mechanism that includes a combination of flowing a current along a second lead of the plurality of second leads and applying a voltage to a first lead of the plurality of first leads.
